(19) United States
(12) Patent Application Publication
(10) Pub. No.: US 2014/0283908 A1
(43) Pub. Date: Sep. 25, 2014

(54) CONCENTRATED PHOTOVOLTAIC RECEIVER WITH FIXING STRUCTURE

(71) Applicant: ATOMIC ENERGY COUNCIL-INSTITUTE OF NUCLEAR ENERGY RESEARCH, (US)

(72) Inventors: YI-PING LIANG, Taoyuan County (TW); HWA-YUH SHIN, Taoyuan County (TW); HUNG-SHENG CHIU, Taoyuan County (TW); HWEN-FEN HONG, Taoyuan County (TW)

(73) Assignee: ATOMIC ENERGY COUNCIL-INSTITUTE OF NUCLEAR ENERGY RESEARCH, Taoyuan County (TW)

(21) Appl. No.: 13/847,548

(22) Filed: Mar. 20, 2013

(51) Int. Cl. H01L 31/052

(52) U.S. Cl. CPC H01L 31/0525
USPC 136/259

(57) ABSTRACT

A concentrated photovoltaic receiver with a fixing structure includes a support member to support and position a light homogenizer. The light homogenizer won't incline or come off due to gravity or other factors during sun-tracing process of the concentrated photovoltaic module. Besides, the support member has a through hole corresponding in position to a concentrated photovoltaic cell and functioning as a fixture for the light homogenizer, such that the light homogenizer can be connected to the concentrated photovoltaic cell at an accurate position and height. Through the structure of the support member, the present invention can prevent the external mist, greasy dirt, dust or the like from adhering to the outer walls of the light homogenizer.

### BACKGROUND OF THE INVENTION

1. Field of the Invention

The present invention relates to a concentrated photovoltaic receiver, and more particularly, to a modularized concentrated photovoltaic receiver with a fixing structure.

2. Description of the Prior Art

Concentrated photovoltaic technology uses optics such as Fresnel lens or curved mirrors to concentrate a large amount of sunlight onto a small area of solar photovoltaic cells to generate electricity. Through a Fresnel lenses, the sunlight is concentrated onto a transparent light-guide cylinder which has a reverse pyramid-like shape, namely, a light homogenizer. The lower end of the light homogenizer has a flat surface to homogenize the light-spot energy from the Fresnel lenses. If the light-spot energy is not first homogenized by the light homogenizer and direct shines on the solar photovoltaic cell, the energy will be too concentrated, which lowers the efficiency to turn the sunlight into electricity. Besides, the angle of the sunlight is changing throughout the day. The concentrated photovoltaic module must cooperate with a sun-tracing system. The sun-tracing system will adjust the angle to get the most sunshine. One of the functions of the light homogenizer is to improve the angle tolerance of the concentrated photovoltaic module. It can also improve the assembly tolerance of the module. Therefore, the light homogenizer is a very important functional element.

In the past, the light homogenizer is installed manually. For the demand of function, the light homogenizer is top-heavy. A layer of adhesive material is provided between the light homogenizer and the concentrated photovoltaic cell to bond both. Sometimes, the support strength is not enough so that the concentrated photovoltaic module may incline and come off easily. Besides, the junction between the light homogenizer and the concentrated photovoltaic cell will accumulate the heat of concentrated light, and therefore the temperature there is high. If the adhesive material is softened by heat and is unable to support the light homogenizer, the light homogenizer will incline and influence its function and reliability.

To consider the main function of the light homogenizer, the incident light is totally reflected by the glass wall of the light homogenizer. If the glass wall has dust, water drop or other contaminants, the condition for total reflection will be destroyed and cause light leak, such that the light cannot be reflected to the concentrated photovoltaic cell. This will influence the efficiency of the light homogenizer and the conversion efficiency of the concentrated photovoltaic receiver greatly.

Furthermore, the contact interface between the light homogenizer and the glue may have the problem of light leak. Because the light homogenizer is installed manually, the glue may be pressed by the light homogenizer to overflow to the lower surface of the side of the light homogenizer, if there is no auxiliary device to fix the installation height of the light homogenizer. The glue attached to the lower surface of the side of the light homogenizer will cause loss of light energy, and therefore lower the efficiency of the concentrated photovoltaic receiver.

Due to the unstable connection of the light homogenizer, which may lower the efficiency of the concentrated photovoltaic receiver, the inventor of the present invention has devoted himself based on his many years of practical experiences to solve these problems.

### SUMMARY OF THE INVENTION

The primary object of the present invention is to provide a concentrated photovoltaic receiver with a fixing structure by using a support member to support and position a light homogenizer. With this fixing structure, the light homogenizer won't incline or come off because of gravity or other factors during sun-tracing process of the concentrated photovoltaic module.

A further object of the present invention is to provide a concentrated photovoltaic receiver with a fixing structure, wherein the support member functions as a fixture for the light homogenizer, such that the light homogenizer can be connected to the concentrated photovoltaic cell at an accurate position and height, and therefore it can be in the best working condition.

Another object of the present invention is to provide a concentrated photovoltaic receiver with a fixing structure, through the air-isolated structure of the support member, the present invention can prevent the external mist, greasy dirt, dust or the like from adhering to the outer walls of the light homogenizer, such that the light homogenizer can keep high efficiency of total reflection for a long time.

In order to achieve the aforesaid objects, the concentrated photovoltaic receiver with a fixing structure comprises a base, a concentrated photovoltaic cell disposed on the base, a support member and a light homogenizer. The support member comprises at least one fixing portion, a support body and a through hole. The fixing portion is located at two sides of the concentrated photovoltaic cell and has a bottom surface attached to the base. The support body is connected with the fixing portion and has a space to accommodate the concentrated photovoltaic cell. The through hole is formed on the top of the support body is located above the concentrated photovoltaic cell. The light homogenizer is inserted through the through hole and located above the concentrated photovoltaic cell. Thus, when the concentrated photovoltaic receiver is running, the light homogenizer is positioned and won't be inclined so as to keep its work efficiency.

### BRIEF DESCRIPTION OF THE DRAWINGS

FIG. 1 is a sectional view of the present invention;

FIG. 2A is a perspective view showing the support member of the present invention;

FIG. 2B is a sectional view showing the support member of the present invention;

FIG. 3A, FIG. 3B and FIG. 3C are schematic views showing installation of the present invention;

FIG. 4 is a schematic view showing the glue layer of the present invention; and

FIG. 5 is a perspective view showing another embodiment of the support member of the present invention.

### DETAILED DESCRIPTION OF THE PREFERRED EMBODIMENTS

Embodiments of the present invention will now be described, by way of example only, with reference to the accompanying drawings.

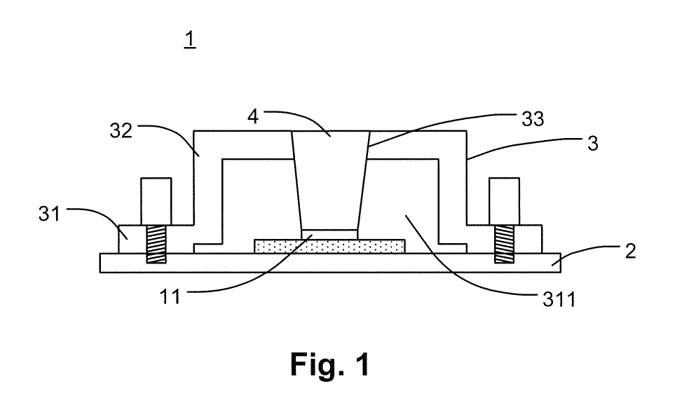

FIG. 1 is a sectional view of the concentrated photovoltaic receiver 1 with a fixing structure of the present invention after assembled. The present invention comprises a base 2, a concentrated photovoltaic cell 11, a support member 3, at least one fixing portion 31, a support body 32, a through hole 33, and a light homogenizer 4.

The base 2 is to bear all the parts and provides a threaded connection function. The concentrated photovoltaic cell 11 and the support member 3 are disposed on the base 2. The support member 3 comprises two portions, the fixing portion 31 and the support body 32. The through hole 33 is formed on the top of the support body 32. The light homogenizer 4 is inserted through the through hole 33 to touch the concentrated photovoltaic cell 11.

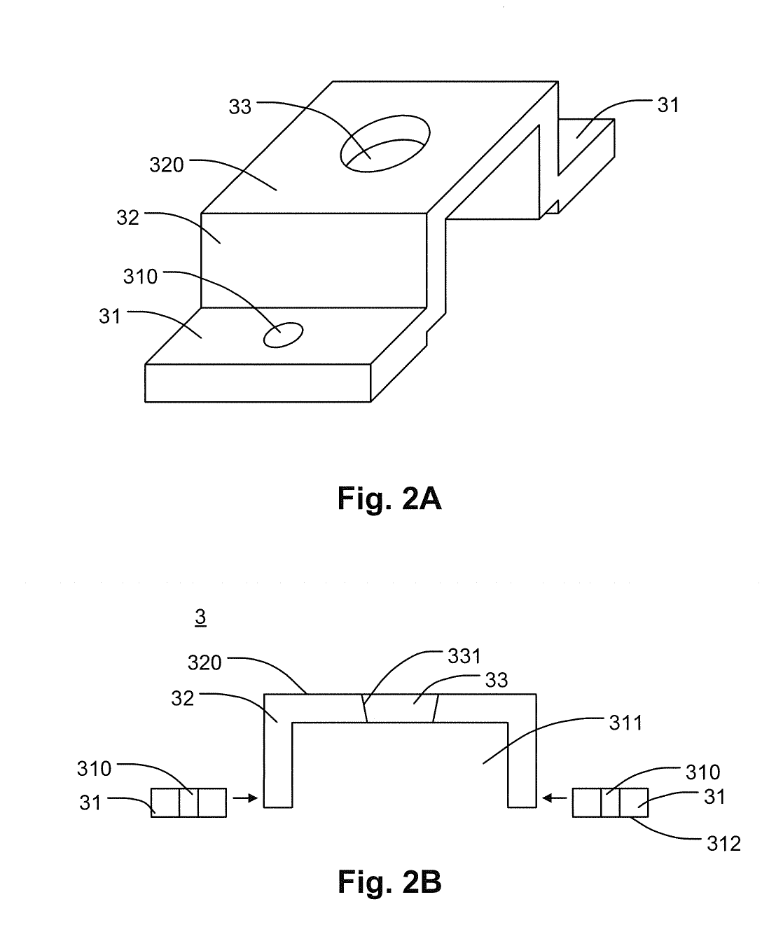

FIG. 2A and FIG. 2B show the support member 3 used to fix and support the light homogenizer 4. The support member 3 is the most important technical feature of the present invention. As shown in the drawings, the fixing portion 31 of the support member 3 is located at two sides of the support member 3 and is also located at two sides of the concentrated photovoltaic cell 11. The fixing portion 31 has a bottom surface 312. The bottom surface 312 is attached to a surface of the base 2 by a threaded connection, without using adhesive. The fixing potion 31 has a first threaded hole 310 for insertion of a bolt to connect the base 2.

The support body 32 of the support member 3 is connected with the fixing portion 31. A space 311 is defined in the support member 3 to accommodate the concentrated photovoltaic cell 11. The support body 32 is a cover-type or a cap-type configuration, and has a reverse U cross-section having the space 311 therein. The support body 32 has a top 320 with the through hole 33. The through hole 33 corresponds in position to the concentrated photovoltaic cell 11 so that the light homogenizer 4 can be inserted through the through hole 33 and aligned to the concentrated photovoltaic cell 11 in order to evenly distribute the sunlight onto the concentrated photovoltaic cell 11. In addition, the diameter of the through hole 33 is tapered downward. The through hole 33 has an inclined inner wall 331 to mate with the configuration of the light homogenizer 4.

FIG. 2B is an exploded view of the support member 3. The fixing portion 31 is integrally formed with the support body 32. The material of the support member 3 can be metal, optical macromolecule synthetic resin, quartz, glass, or other materials which can bear high temperature or can transmit the light.

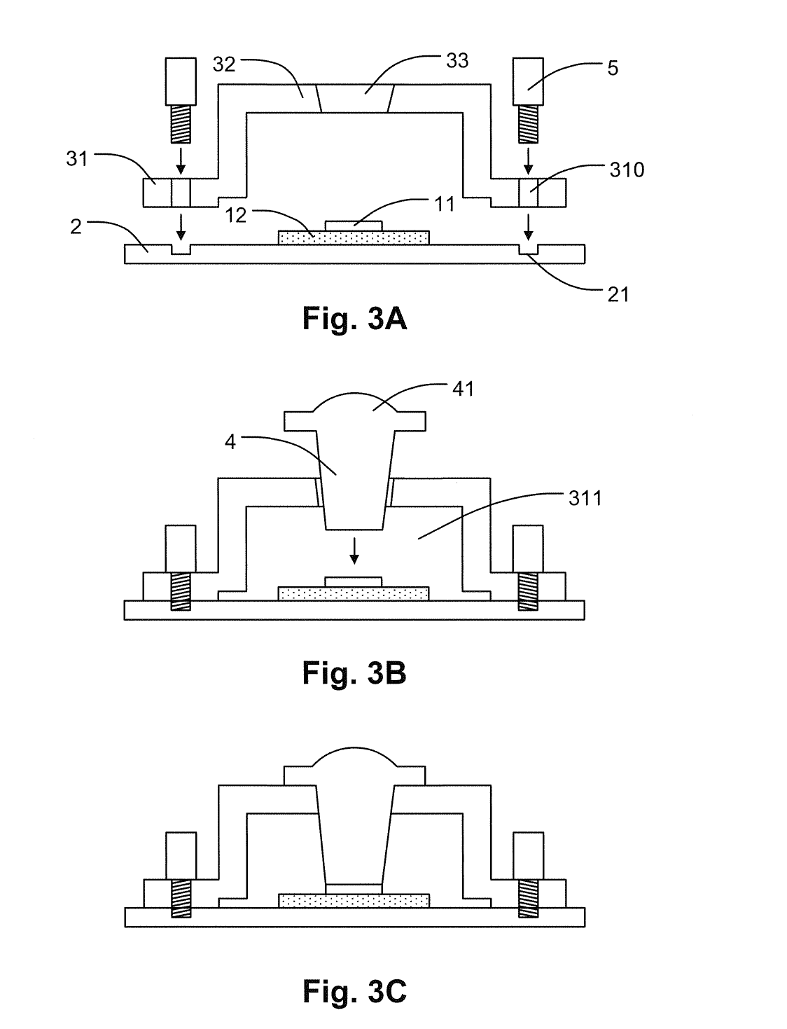

FIG. 3A, FIG. 3B and FIG. 3C are schematic views to show assembly of the concentrated photovoltaic receiver with a fixing structure of the present invention. In order to fix the support member 3 to the base 2, the base 2 has at least one second threaded hole 21 so that a bolt 5 can be inserted through the first threaded hole 310 of the support member 3 and the second threaded hole 21 of the base 2 to connect the support 3 and the base 2.

Due to the demand of function, the configuration of the light homogenizer 4 is not limited to a reverse trapezoid cylinder and it can have other shapes such as a paraboloid body (like a bullet) or a hemisphere body. As a whole, the light homogenizer 4 is a solid transparent body which has a large upper part and a small lower part so as to be inserted into the through hole 33. Through the inclined inner wall 331 of the through hole 33, the light homogenizer 4 is retained at a certain height and won't incline, at the same time, the upper slab of the light homogenizer 4 is retained by the top 320 of the support body 32. The position and diameter of the through hole 33 and the top 320 of the support body 32 provide a positioning function to the light homogenizer 4 so that the light homogenizer 4 won't incline or come off because of gravity or other factors during sun-tracing process of the concentrated photovoltaic module.

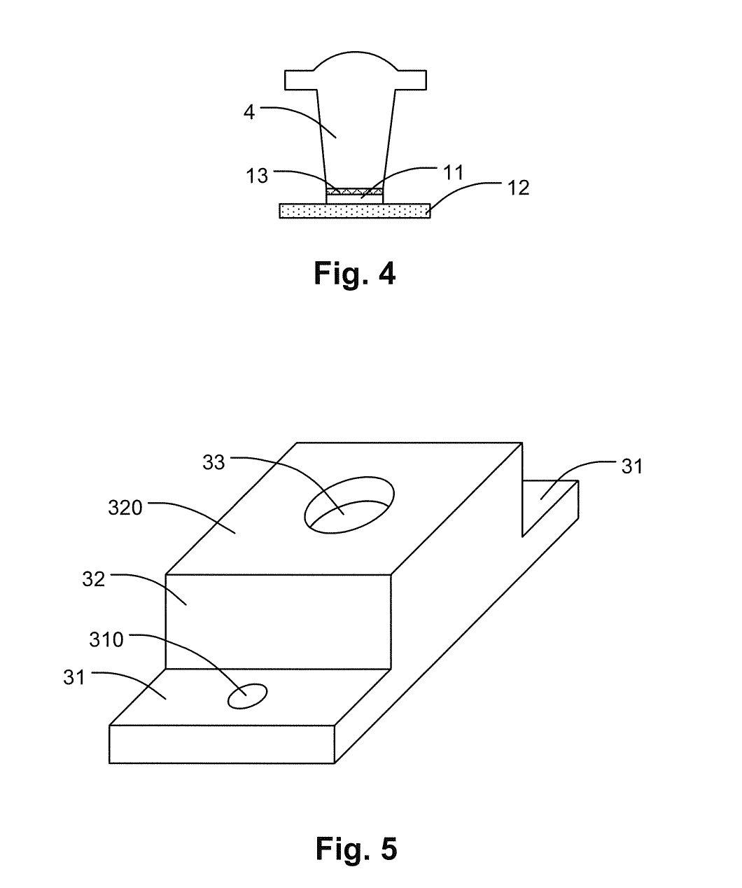

The material of the light homogenizer 4 is transparent optic macromolecule synthetic resin, glass, quartz, or other materials which can transmit the sunlight. The process to make the light homogenizer 4 can be die-casting, grind, molding or injection, but not limited to these. Referring to FIG. 4, a glue layer 13 is provided between the bottom of the light homogenizer 4 and the concentrated photovoltaic cell 11 to bond the light homogenizer 4 and the concentrated photovoltaic cell 11 so as to enhance the fixing effect of the light homogenizer 4. The glue layer 13 is light-transmitting insulating glue so it won't influence the current path of the concentrated photovoltaic receiver.

Because the height of the light homogenizer 4 and the height of the support member 3 are well designed, the lamination condition between the bottom of the light homogenizer 4 and the concentrated photovoltaic cell 11 can be controlled stably. Thus, the glue won't be pressed to overflow and attach to the side of the light homogenizer 4, which will cause the light leak.

FIG. 3B shows another embodiment of the light homogenizer 4. In this embodiment, the light homogenizer 4 further comprises a cap configuration 41. The cap configuration 41 will be against the top 320 of the support body 32 after the light homogenizer 4 is inserted in the through hole 33. The cap configuration 41 can provide a specific optics effect to shorten the optical path and decrease the height of the light homogenizer 4.

The concentrated photovoltaic cell 11 of the present invention is disposed on the insulation base 12, which is prior art and won't be described in detail about the arrangement of the metallic electrodes therebetween.

Besides, the support member 3 provides a protection function to prevent the light homogenizer 4 from being attached by the external contaminant. FIG. 5 shows another embodiment of the support member 3 of the present invention. After the support member 3 is connected to the base 2 and the light homogenizer 4 is inserted in the through hole 33, the support body 32 forms a closed space 311 therein. The lower part of light homogenizer 4 is isolated in the closed space in order to prevent external mist, greasy dirt, dust or the like from adhering to the outer walls of the light homogenizer 4, such that the light homogenizer 4 can keep a high efficiency of total reflection for a long time. The closed space can also be vacuumed, or filled with dry air, nitrogen or inert gas to ensure a clean closed space in order to maintain the light homogenizer 4 and concentrated photovoltaic cell 11 in the best working state.

The concentrated photovoltaic receiver with a fixing structure of the present invention has many advantages. Through the support member supporting and positioning the light homogenizer, the light homogenizer won't incline or come off because of gravity or other factors during sun-tracing process of the concentrated photovoltaic module. Besides, the through hole of the support member corresponds in position to the concentrated photovoltaic cell and functions as a fixture for the light homogenizer, such that the light homogenizer can be connected to the concentrated photovoltaic cell at an accurate position and height. Through the structure of the support member, the present invention can also prevent the external mist, greasy dirt, dust or the like from adhering to the outer walls of the light homogenizer, such that the light homogenizer can keep a high efficiency of total reflection for a long time. For quick and accurate installation of the light homogenizer as well as better light efficiency and even light effect, the concentrated photovoltaic receiver with a fixing structure, the present invention, is very practical.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A concentrated photovoltaic receiver with a fixing structure, comprising:
a base;
a concentrated photovoltaic cell disposed on the base;
a support member, the support member comprising:
at least one fixing portion, located at one side of the concentrated photovoltaic cell and having a bottom surface attached to the base;
a support body, connected with the fixing portion and having a space to accommodate the concentrated photovoltaic cell; and
a through hole, formed in the top of the support body, the through hole being located above the concentrated photovoltaic cell; and
a light homogenizer, inserted through the through hole and located above the concentrated photovoltaic cell.

2. The concentrated photovoltaic receiver with a fixing structure as claimed in claim 1, wherein the fixing portion is integrally formed with the support body.

3. The concentrated photovoltaic receiver with a fixing structure as claimed in claim 1, wherein the fixing potion has at least one first threaded hole.

4. The concentrated photovoltaic receiver with a fixing structure as claimed in claim 1, wherein the base has at least one second threaded hole.

5. The concentrated photovoltaic receiver with a fixing structure as claimed in claim 1, wherein the fixing potion is threadedly connected to the base.

6. The concentrated photovoltaic receiver with a fixing structure as claimed in claim 1, wherein the material of the support member is selected from the group consisting of metal, macromolecule synthetic resin, quartz and glass.

7. The concentrated photovoltaic receiver with a fixing structure as claimed in claim 1, wherein the space is a closed space.

8. The concentrated photovoltaic receiver with a fixing structure as claimed in claim 1, wherein the space is vacuumed or filled with a gas selected from the group consisting of dry air, nitrogen and inert gas.

9. The concentrated photovoltaic receiver with a fixing structure as claimed in claim 1, further comprising a glue layer to bond the concentrated photovoltaic cell and the light homogenizer, the glue layer being light-transmitting insulating glue.

10. The concentrated photovoltaic receiver with a fixing structure as claimed in claim 1, wherein the light homogenizer has a cap configuration, the cap configuration being against the top of the support body after the light homogenizer is inserted in the through hole.
